(19) United States
(12) Patent Application Publication
(10) Pub. No.: US 2015/0303036 A1
(43) Pub. Date: Oct. 22, 2015

(54) SUBSTRATE TREATMENT APPARATUS INCLUDING SEALING MEMBER HAVING ATYPICAL SECTION

(71) Applicant: SAMSUNG ELECTRONICS CO., LTD., Suwon-si (KR)

(72) Inventors: Jihoon JEONG, Suwon-si (KR); Gil Hun SONG, Cheonan-si (KR); Ki Sang EUM, Cheonan-si (KR); Yongsun KO, Suwon-si (KR); Kuntack LEE, Suwon-si (KR); Yongmyung JUN, Hwaseong-si (KR); Yong-Jhin CHO, Hwaseong-si (KR)

(73) Assignee: Semes Co., Ltd., Cheonan-si (KR)

(21) Appl. No.: 14/611,618

(22) Filed: Feb. 2, 2015

(30) Foreign Application Priority Data
Apr. 16, 2014 (KR) 10-2014-0045578

(51) Int. Cl. H01J 37/32

(52) U.S. Cl. CPC H01J 37/32513; H01J 2237/332; H01J 2237/334

(57) ABSTRACT

A substrate treatment apparatus includes a seal on at least one of upper or lower chambers of a process chamber. The seal hermetically closes the substrate treatment region, and may be at a location to prevent a gap from forming between the upper and lower chambers. The lower chamber includes an inner wall and an outer wall defining a groove including the seal. The inner wall has a top surface lower than that of the outer wall. The seal has an atypical cross-sectional shape with a recess facing the substrate treatment region.

### CROSS-REFERENCE TO RELATED APPLICATION

Korean Patent Application No. 10-2014-0045578, filed on Apr. 16, 2014, and entitled, “Substrate Treatment Apparatus Including Sealing Member Having Atypical Section,” is incorporated by reference herein in its entirety.

### BACKGROUND

1. Field

One or more embodiments described herein relate to a substrate treatment apparatus including a sealing member having an atypical section.

2. Description of the Related Art

A variety of processes are used to treat a substrate. Examples include deposition, etching, cleaning, and drying processes. These processes may be performed on a substrate (e.g., a silicon wafer) loaded in a sealed process chamber. In order to hermetically seal or close an internal space of the process chamber, a sealing member such as O-ring may be used. When the sealing member is damaged or deformed, the sealed environment of the process chamber may be adversely affected and the substrate treatment process may fail as a consequence.

### SUMMARY

In accordance with one embodiment, a substrate treatment apparatus includes a process chamber including a substrate treatment region between an upper chamber and a lower chamber; and a seal on at least one of the upper or lower chambers to hermetically close the substrate treatment region, wherein the seal is at a location to prevent a gap between the upper and lower chambers, and wherein the lower chamber includes an inner wall and an outer wall defining a groove including the seal, the inner wall has a top surface lower than that of the outer wall, and the seal has an atypical cross-sectional shape with a recess facing the substrate treatment region. The seal may be or may include an O-ring, and the atypical cross-sectional shape may be an atypical circular shape.

The filler may be between the seal and the groove, and the filler may be at a location to reduce a size of a gap between the seal and groove. The filler may have a compressive strain property that is substantially equivalent to or lower than that of the seal. The lower chamber may move toward the upper chamber until the lower and upper chambers are in contact with each other, to hermetically close the substrate treatment region. The lower and upper chambers may be in contact with each other, and the outer wall may be in contact with the upper chamber and the inner wall may be spaced apart from the upper chamber. The outer wall may have a width that increases in a direction from the lower chamber toward the upper chamber, and an inner side surface of the outer wall may slant toward the seal. The groove may have a shape fitted to an appearance of the seal, and the seal may fill the groove.

In accordance with another embodiment, a substrate treatment apparatus may include a substrate treating unit including at least one process chamber, a fluid supply to supply a supercritical fluid to the at least one process chamber, and a supply line valve arrangement to provide a flow path for supplying the supercritical fluid from the fluid supply to the substrate treating unit, the supply line valve arrangement including at least one supply line that includes a valve

The at least one process chamber includes upper and lower chambers defining a substrate treatment region and having an open/closed state that corresponds to positions of the upper and lower chambers; and a seal between the upper and lower chambers to hermetically close the substrate treatment region when the upper and lower chambers are in contact with each other. The lower chamber includes inner and outer walls defining a groove including the seal, the inner and outer walls being adjacent to the substrate treatment region and an outside of the process chamber, respectively, a top surface of the inner wall is farther from the upper chamber than a top surface of the outer wall, and the seal is or includes an O-ring having a atypical cross-section with a recess adjacent to the top surface of the inner wall.

The apparatus may include a cylinder coupled with the lower chamber to provide a driving force to move the lower chamber toward the upper chamber; and a rod defining a path to guide the lower chamber toward the upper chamber, wherein the lower chamber is to move toward the upper chamber by the driving force from the cylinder until the lower and upper chambers are in contact with each other, to thereby hermetically close the substrate treatment region.

When the lower and upper chambers are in contact with each other, the top surface of the outer wall may be in contact with the upper chamber and the top surface of the inner wall is spaced apart from the upper chamber. The outer wall may have an inner side surface slanted toward the O-ring, and the groove may include a top entrance adjacent to the upper chamber and a bottom surface having a width less than that of the top entrance.

The apparatus may include a filler between the O-ring and the groove to reduce a size of a gap between the O-ring and the groove, and the filler may include a polymer having a compressive strain substantially equivalent to or lower than that of the O-ring. The O-ring and the filler may include at least one of polytetrafluoroethylene, perfluoroalkoxy, polyimide, polyethylene, polychlorotrifluoroethylene, urethane, or fluorine-based resins. The O-ring may include at least one of polytetrafluoroethylene, perfluoroalkoxy, polyimide, polyethylene, polychlorotrifluoroethylene, urethane, or fluorine-based resins, and the filler may include at least one of polyetheretherketone, polyvinylidenefluoride, methycellulose, nylon, polyamideiminde, polybenzimidazole, polycarbonate, or polyethyleneterephthalate.

In accordance with another embodiment, a chamber for treating a substrate includes a surface, a groove in the surface, and a seal in the groove, wherein the seal has a first cross-sectional shape when uncompressed and a second cross-sectional shape when compressed, and wherein the first cross-sectional shape is an atypical shape and the second cross-sectional shape does not overlap the surface at any area adjacent the groove.

The first cross-sectional shape may be substantially a waxing or waning gibbous moon shape. A side wall of the groove in the surface may be slanted in a direction toward the seal. The chamber may include a filler material in the groove, and the filler material may be between the seal and a wall of the groove. A top surface of the seal may extend above the surface when uncompressed.

### BRIEF DESCRIPTION OF THE DRAWINGS

Features will become apparent to those of skill in the art by describing in detail exemplary embodiments with reference to the attached drawings in which:

FIG. 1A illustrates an embodiment of a substrate treatment apparatus, FIG. 1B illustrates another embodiment of a substrate treatment apparatus, FIG. 1C illustrates a an embodiment of a process chamber, and FIG. 1D illustrates a plan view of FIG. 1C;

FIG. 2A illustrates a cross-sectional view of the process chamber of FIG. 1C having an open substrate treatment region, FIG. 2B illustrates a cross-sectional view of the process chamber of FIG. 1C having a closed substrate treatment region, FIG. 2C illustrates a cross-sectional view of the process chamber in FIG. 2A, FIG. 2D illustrates a cross-sectional view of a comparative example of a portion in FIG. 2C, and FIGS. 2E and 2F illustrate modified examples of an O-ring;

FIG. 3A illustrates a comparative example of a portion in FIG. 2A, and FIG. 3B illustrates a comparative example of a portion in FIG. 2B;

FIGS. 4A through 4C illustrate modified examples of the portion in FIG. 2A;

FIGS. 5A to 5C illustrate other modified examples of the portion in FIG. 2A;

FIGS. 6A to 6C illustrate other modified examples of the portion in FIG. 2A; and

FIGS. 7A and 7B illustrate other modified examples of the portion in FIG. 2A.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawings, the dimensions of layers and regions may be exaggerated for clarity of illustration. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

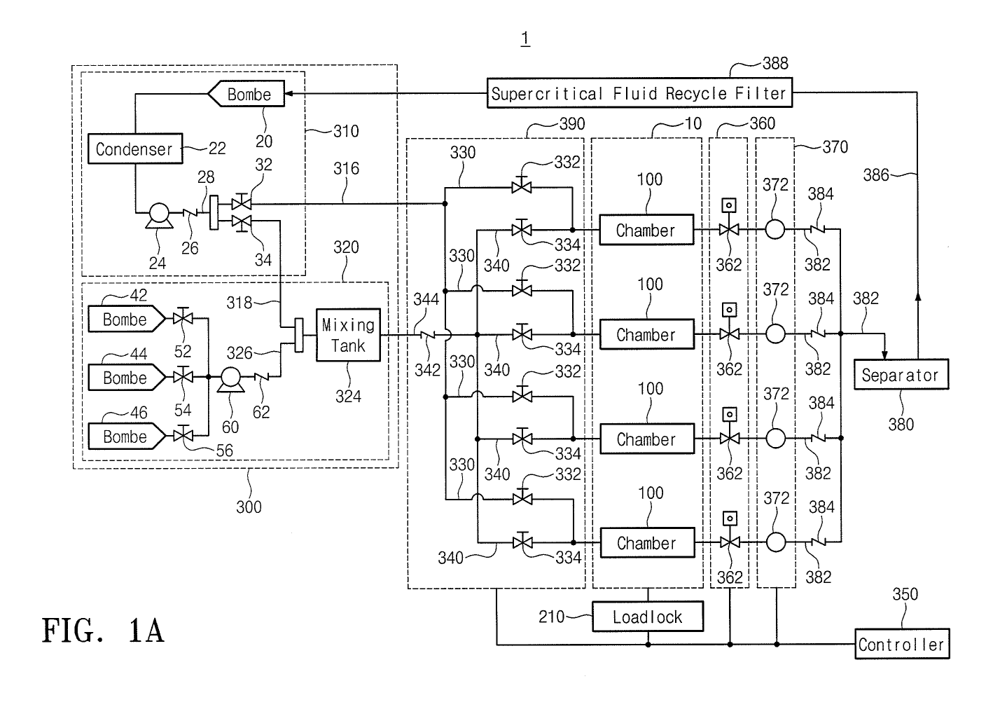

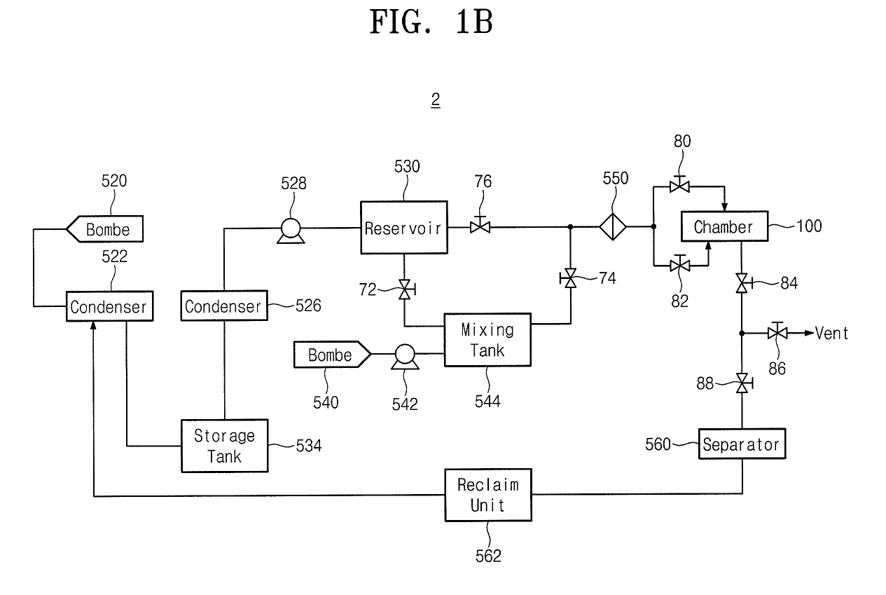

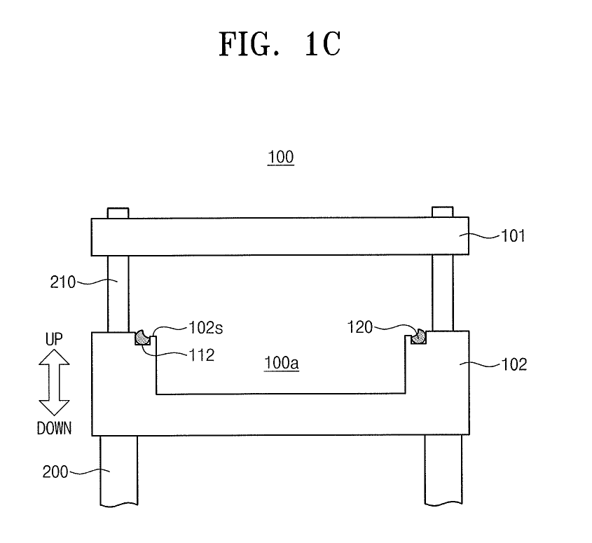

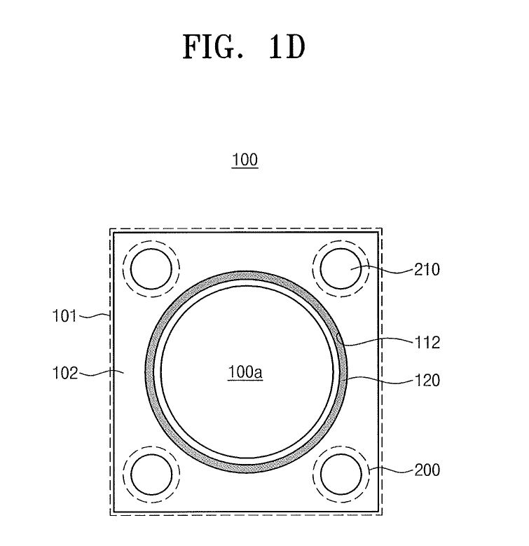

FIG. 1A illustrates an embodiment of a substrate treatment apparatus 1 which includes a substrate treating unit 10, a fluid supply unit 300, and a supply line valve unit 390. The substrate treating unit 10 may treat a substrate, for example, using supercritical fluid. The fluid supply unit 300 may supply the supercritical fluid to the substrate treating unit 10. The supply line valve unit 390 may provide a supply path for the supercritical fluid from the fluid supply unit 300 to the substrate treating unit 10.

The substrate treating unit 10 may include at least one process chamber 100.

The supercritical fluid from the fluid supply unit 300 may perform, for example, one or more of a cleaning, drying, or etching treatment on a substrate loaded in the process chamber 100.

The fluid supply unit 300 may include a first supplying part 310 for supplying the supercritical fluid to the substrate treating unit 10, and a second supplying part 320 for providing a fluid mixture of the supercritical fluid and a second fluid. The supercritical fluid may include, for example, supercritical carbon dioxide. The second fluid may include, for example, a co-solvent, a fluorine-containing compound, or a mixture thereof. The co-solvent may be, for example, methanol, ethanol, isopropyl alcohol (IPA), or propanol. Different fluids, solvents, or compounds may be used in other embodiments.

The first supplying part 310 may include a bombe 20 containing a material (e.g., CO₂) for the supercritical fluid. The material contained in the bombe 20 may be supplied to a condenser 22 as a liquid at a predetermined pressure, e.g., about 800 psi. The condenser 22 compresses the liquid material from the bombe 20 at a predetermined pressure (e.g., a higher pressure than 800 psi) to create a supercritical fluid. The supercritical fluid that escapes from the condenser 22 may have a higher pressure (e.g., about 2,000 to 3,500 psi) as it passes through a booster pump 24. The supercritical fluid may be transferred to first or second branch line 316 or 318, depending on opening/closing operations of valves 26, 32, and 34 mounted on supply lines behind the booster pump 24. Valve 26 may be a check valve mounted on a supply line 28. The valves 32 and 34 may be mounted on first and second branch lines 316 and 318, respectively.

The second supplying part 320 may include a plurality of bombes 42, 44, and 46 containing various kinds of materials of the second fluid. The materials in the bombes 42, 44, and 46 may be transferred to the substrate treating unit 10 through the supply line 326, depending on opening/closing operations of the valves 52, 54, and 56. In one embodiment, a booster pump 60 may be mounted on the supply line 326 to increase the pressure of the second fluid from bombes 42, 44, and 46. A check valve 62 may be installed on the supply line 326 to control transfer operation of the second fluid.

The second supplying part 320 may further include a mixing tank 324, in which the supercritical fluid transferred through the second branch line 318 and the second fluid transferred through the supply line 326 are mixed. The fluid mixture in the mixing tank 324 may be supplied to the supply line valve unit 390 through a supply line 344. The supply of the fluid mixture may be controlled by adjusting an open/closed state of a check valve 342 installed on the supply line 344.

The supply line valve unit 390 may include first supply lines 330 (which are used to transfer the supercritical fluid to the process chambers 100, respectively) and second supply lines 340 (which are used to transfer the fluid mixture to the process chambers 100, respectively). The supercritical fluid from the first supplying part 310 may be supplied into the process chambers 100, respectively, through the first supply lines 330 connected to the first branch line 316. The operation of supplying the supercritical fluid from the first supplying part 310 to the process chambers 100 may be controlled by adjusting open/closed states of first valves 332 respectively installed on the first supply lines 330. The fluid mixture transferred from the second supplying part 320 may be supplied into the process chambers 100, respectively, through the second supply lines 340 connected to the supply line 344. The operation of supplying the fluid mixture from the supply line 344 to the process chambers 100 may be controlled by adjusting open/closed states of second valves 334 respectively installed on the second supply lines 340.

The substrate treatment apparatus 1 may include a controller 350 for controlling an operation of treating one or more process chambers 100 using the supercritical fluid and/or the second fluid. The controller 350 may selectively control the open/closed state of each of the check valve 342, the first valves 332, and the second valves 334. This may make it possible to selectively supply the supercritical fluid or the fluid mixture to at least one of the process chambers 100. As an example, the controller 350 may be operated in such a way that the supercritical fluid or the fluid mixture is supplied to one of the process chambers 100. As another example, the controller 350 may be operated in such a way that the supercritical fluid and the fluid mixture are supplied to two different ones, respectively, of the process chambers 100 at the same time or with any interval.

The substrate treatment apparatus 1 may further include at least one of a load lock 210 for loading and unloading the substrate, a treatment time controller 360 for controlling the process time of the substrate treatment, or a pressure adjusting unit 370 for adjusting pressure of the process chamber 100.

The load lock 210 may be provided near the process chambers 100, to load or unload the substrate to or from a selected one of the process chambers 100 based on control of the controller 350. Exhaust lines 382 may be connected to the process chambers 100. The treatment time controller 360 may include timers 362 installed on the exhaust lines 382, respectively. The pressure adjusting unit 370 may include pressure regulators 372 such as a back-pressure regulator installed on the exhaust lines 382, respectively. The load lock 210, the treatment time controller 360, and the pressure adjusting unit 370 may be controlled by the controller 350. Check valves 384 may be installed on the exhaust lines 382, respectively, to control flow of the fluid exhausted from the process chambers 100.

The substrate treatment apparatus 1 may neutralize or recover the supercritical fluid or the fluid mixture. As an example, the substrate treatment apparatus 1 may include a separator 380 (in which a fluidic material transferred from the exhaust lines 382 is collected) and a supercritical fluid recovering filter 388 to filter out a supercritical fluid from the exhausted fluid stored in the separator 380.

The separator 380 may also separate a supercritical fluid containing material from the exhausted fluid discharged from the process chambers 100. The supercritical fluid, containing material separated by the separator 380, may be transferred to the supercritical fluid recovering filter 388 through a recycle line 386. A supercritical fluid may be extracted from a material transferred from the separator 380 in the supercritical fluid recovering filter 388, and may be transferred to and stored in the bombe 20 of the first supplying part 310.

The separator 380 may also neutralize the exhausted fluid discharged from the process chambers 100. In the case where hydrogen fluoride (HF) or a HF-containing fluid is discharged from the process chamber 100, a NaOH solution may be contained in the separator 380 to neutralize the hydrogen fluoride. For example, if an acid material is discharged from the process chambers 100, an alkaline solution is provided within the separator 380. Conversely, if an alkaline material is discharged from the process chambers 100, an acid solution is provided within the separator 380.

FIG. 1B illustrates another embodiment of a substrate treatment apparatus 2 which includes a bombe 520 containing a source material (e.g., CO₂) to be used as a supercritical fluid, a bombe 540 containing a second fluid (e.g., a co-solvent), a mixing tank 544, in which the supercritical fluid and the second fluid are mixed, and the process chamber 100, in which a supercritical treatment process using the supercritical fluid or the fluid mixture is performed.

A material (for example, in a liquid state) stored in the bombe 520 may be transferred to and stored in a storage tank 534. A condenser 522 may be provided on a supply line connecting the bombe 520 to the storage tank 534, to compress the material transferred from the bombe 520 to the storage tank 534. The material in the storage tank 534 may be further compressed by a condenser 526 and a booster pump 528, and then contained in a reservoir 530. As a result of the compression, the material transferred from the storage tank 534 may be changed to a phase of a supercritical fluid and may be stored in the reservoir 530. The supercritical fluid in the reservoir 530 may be supplied to the process chamber 100 or the mixing tank 544, depending on open/closed states of valves 72 and 76.

The second fluid in the bombe 540 may be compressed by a booster pump 542, and may then be supplied to the mixing tank 544. The second fluid and the supercritical fluid from the reservoir 530 may be mixed in the mixing tank 544 to form a fluid mixture. The fluid mixture may be supplied to the process chamber 100, depending on an open/closed state of a valve 74.

The supercritical fluid or the fluid mixture may be filtered by a filter 550 between the reservoir 530 or mixing tank 544 and the process chamber 100. After filtering, the supercritical fluid or the fluid mixture may be supplied to the process chamber 100 depending on open/closed states of valves 80 and 82, and may be used for a supercritical treatment process to be performed in the process chamber 100.

A fluidic material discharged from the process chamber 100 may be discarded or collected in a separator 560, depending on the open/closed states of the valves 84, 86, and 88. The fluidic material in the separator 560 may be transferred to the condenser 522 through a reclaim unit 562. In the condenser 522, the fluidic material may be compressed to become a supercritical fluid, which may be re-used in the supercritical treatment process.

FIG. 1C illustrates an embodiment of a process chamber 100, and FIG. 1D is a plan view of FIG. 1C. Referring to FIG. 1C, in the substrate treatment apparatus 1 or 2 of FIG. 1A or 1B, the process chamber 100 may include an upper chamber 101 and a lower chamber 102. At least one of the upper or lower chambers 101 and 102 may be able to move upward or downward, to thereby selectively change an open/closed state of a substrate treatment region 100a.

For example, the lower chamber 102 may be coupled with a cylinder 200 and may be moved upward or downward along a rod 210, in conjunction with the cylinder 200. The rod 210 may include an end portion inserted into the cylinder 200 and an opposite end portion coupled to the upper chamber 101. The upper and lower chambers 101 and 102 may be formed of, for example, stainless steel (SUS).

The cylinder 200 may exert a driving force on the lower chamber 102. The driving force may allow for upward movement of the lower chamber 102 along the rod 210. When the lower chamber 102 is moved upwardly to contact the upper chamber 101, the substrate treatment region 100a may be closed or sealed. A substrate treatment process may be performed on a substrate in the sealed substrate treatment region 100a.

For example, a supercritical fluid (e.g., of carbon dioxide) may be supplied in the substrate treatment region 100a and may be used to perform a supercritical treatment process (e.g., a drying or cleaning process) on the substrate. In one embodiment, the process chamber 100 may be used to perform other processes (such as a deposition or etching process) other than a supercritical treatment process.

By moving the lower chamber 102 upward and controlling supplying of pressure of a gas into the substrate treatment region 100a, an internal pressure of the substrate treatment region 100a may be increased to a desired pressure (for example, up to several ten to several hundred bars) for a supercritical treatment process.

To hermetically seal, or close, the substrate treatment region 100a in the high pressure environment, a sealing member such as an O-ring 120 may be provided between the upper and lower chambers 101 and 102. The O-ring 120 may be inserted into a groove 112 on a top surface 102s of the lower chamber 102. The groove 112 may be adjacent to the substrate treatment region 100a.

The O-ring 120 may be used to form or maintain a high-pressure supercritical environment in the substrate treatment region 100a. In another embodiment, the O-ring 120 may be used to form or maintain a specific pressure environment (e.g., vacuum or atmospheric pressure) in the substrate treatment region 100a. Thus, the O-ring 120 may serve diverse purposes associated with sealing a space between the upper and lower chambers 101 and 102.

As shown in FIG. 1D, the substrate treatment region 100a may have, for example, a circular shape when viewed in top plan view. The O-ring 120 may have a ring shape extending along an outer circumference of the substrate treatment region 100a, and may be inserted into the groove 112.

The O-ring 120 may be made from or include, for example, polymer. For example, the O-ring 120 may include at least one of polytetrafluoroethylene (PTFE), perfluoroalkoxy (PFA), polyimide, polyethylene, polychlorotrifluoroethylene (PCTFE), urethane, or fluorine-based resins, or a combination thereof.

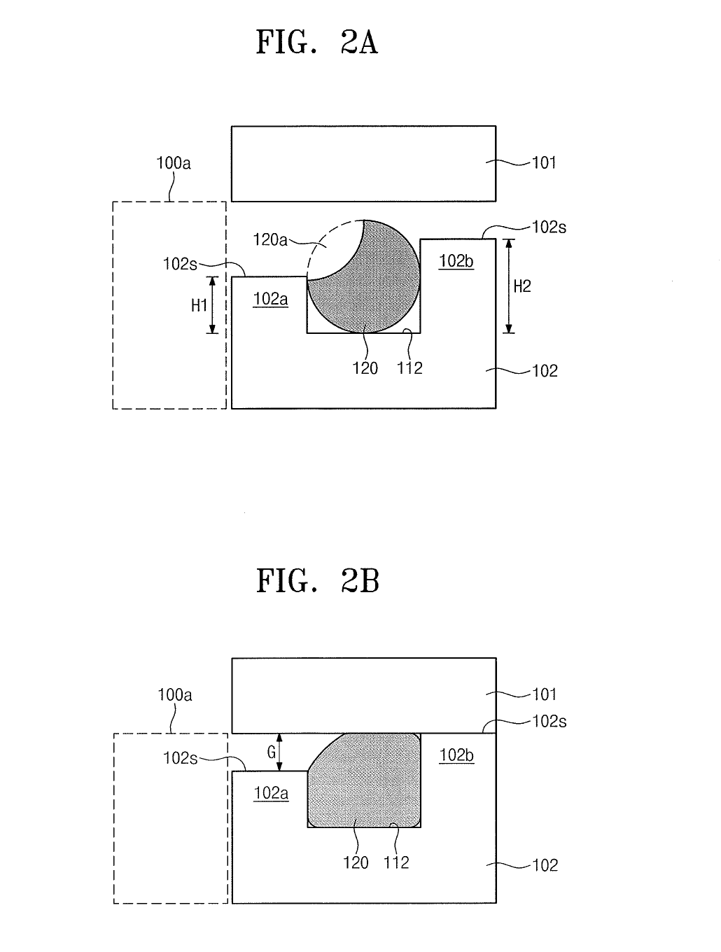

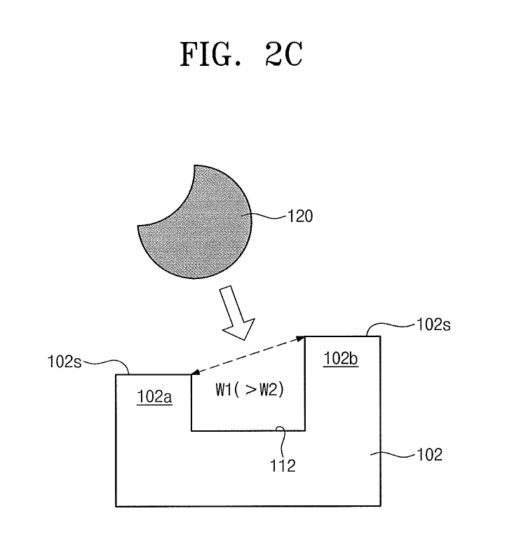

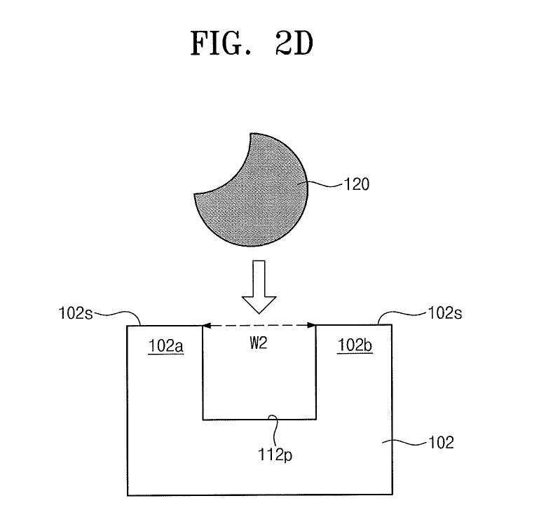

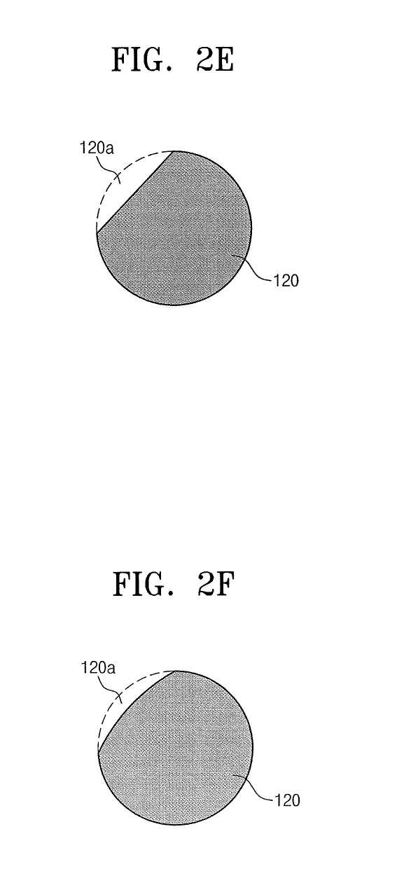

The O-ring may have a circular cross-section. In another embodiment, the O-ring ring 120 may have an atypical or non-geometrical cross-section different from such a circular shape, as will be described, for example, with reference to FIG. 2A. In at least one embodiment, a circular cross-section may be referred to as a typical cross-section and a non-circular cross-section may be referred to as an atypical cross-section.

FIG. 2A illustrates the process chamber of FIG. 1C having an open substrate treatment region, and FIG. 2B illustrates the process chamber of FIG. 1C having a closed substrate treatment region. FIG. 2C illustrates a portion of the process chamber of FIG. 2A, FIG. 2D is a sectional view illustrating a comparative example of the portion in FIG. 2C, and FIGS. 2E and 2F illustrates modified examples of an O-ring.

Referring to FIG. 2A, according to one embodiment, the O-ring 120 may have a recess 120a or an atypical circular cross-section. For example, the O-ring 120 may have a atypical circular cross-section shaped like a waxing gibbous moon. The O-ring 120 may be inserted into the groove 112 in such a way that the recess 120a is positioned toward the substrate treatment region 100a. The recess 120a may have an oval cross-section. In another embodiment, the recess 120a may have various other atypical cross-sectional shapes. For example, the recess 120a may have a cross-sectional shape like a waning half moon as in FIG. 2E or a waning crescent moon as in FIG. 2F.

According to one embodiment, the groove 112 may prevent the O-ring 120 from being separated from its installed position by a high pressure environment in the substrate treatment region 100a, when at least one of the upper and lower chambers 101 and 102 is moved to seal the substrate treatment region 100a as shown in FIG. 2B.

For example, a portion of the lower chamber 102 adjacent to the substrate treatment region 100a may be used as an inner wall 102a of the groove 112. Another portion of the lower chamber 102, adjacent to the outside of the process chamber 100 or apart from the substrate treatment region 100a, may be used as an outer wall 102b of the groove 112. A top surface 102s of the inner wall 102a may be at a lower level than that of the outer wall 102b. Due to the difference in height of the top surface 102s of the lower chamber 102, a height H2 of the outer wall 102b may be greater than a height H1 of the inner wall 102a. Because the outer wall 102b is taller than the inner wall 102a, the O-ring 120 may be prevented from being separated from its intended position.

Due to the difference in height of the top surface 102s of the lower chamber 102, the O-ring 120 may be easily installed in or detached from the groove 112, compared with the case where there is no height difference relative to the top surface 102s. For example, as shown in FIG. 2C, if there is the difference in height of the top surface 102s of the lower chamber 102, a width W1 of a top entrance of the groove 112 may be larger than a width W2 of a top entrance of the groove 112p in FIG. 2D. In other words, the widened top entrance of the groove 112 makes it easy to install or detach the O-ring 120 in or from the groove 112.

Referring to FIG. 2B, in the case where the upper and lower chambers 101 and 102 contact each other, the O-ring 120 may be pressured to prevent a gap from forming between the upper and lower chambers 101 and 102. Thus, the substrate treatment region 100a may be hermetically sealed or closed.

Because the height H1 of the inner wall 102a is smaller than the height H2 of the outer wall 102b, a gap G may be formed between the upper chamber 101 and the inner wall 102a, even when the upper and lower chambers 101 and 102 contact each other. The gap G may be spatially connected to the substrate treatment region 100a. According to one embodiment, the O-ring 120 may have an atypical cross-sectional shape. Thus, even if the O-ring 120 is pressured, the O-ring 120 may not protrude into the gap G.

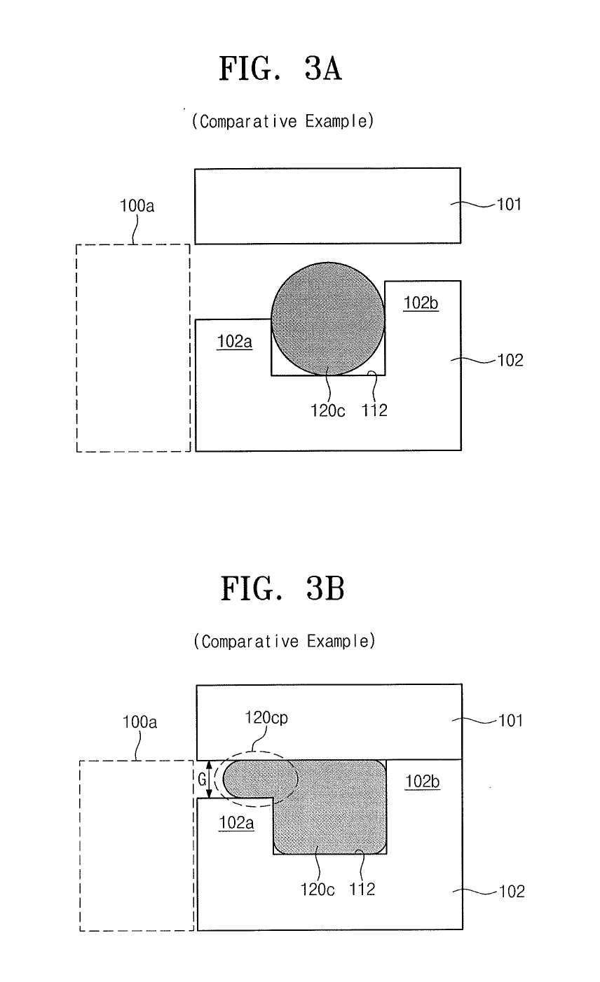

If the O-ring 120 protrudes into the gap G, the O-ring 120 may be damaged or deformed by applied pressure. This may lead to deterioration in the sealing ability of the O-ring 120. Because of this damage or deformation to the O-ring 120, it may be difficult to maintain a high pressure environment in the substrate treatment region 100a and particles may be produced. A example of these problems will be described below with reference to FIGS. 3A and 3B.

FIG. 3A illustrates a comparative example of portion in FIG. 2A, and FIG. 3B illustrates a comparative example of the portion in FIG. 2B.

Unlike the O-ring 120 of the aforementioned embodiments, an O-ring 120c having a typical cross-section may be installed in the groove 112 as shown in FIG. 3A. In this case, as shown in FIG. 3B, when the upper and lower chambers 101 and 102 contact each other, the O-ring 120c may be pressured to have a protruding portion 120cp protruding into the gap G. The protruding portion 120cp may be permanently deformed.

For example, even when the upper and lower chambers 101 and 102 are separated from each other, the shape of the O-ring 120 may not be restored. Such deformation (e.g., swelling) of the O-ring 120 may lead to deterioration in the sealing ability of the upper and lower chambers 101 and 102, difficulty in maintaining a high pressure environment in the substrate treatment region 100a, and/or occurrence of particles.

In contrast, the O-ring 120 according to one or more of the aforementioned embodiments does not have a portion that protrudes, or may have a atypical cross-sectional shape as in FIG. 2A. Accordingly, even when pressure is applied to the O-ring 120 as in FIG. 2B, it is possible to prevent or suppress the O-ring 120 from swelling. As a result, it is possible to maintain a high pressure environment in the substrate treatment region 100a and preventing particles from being produced.

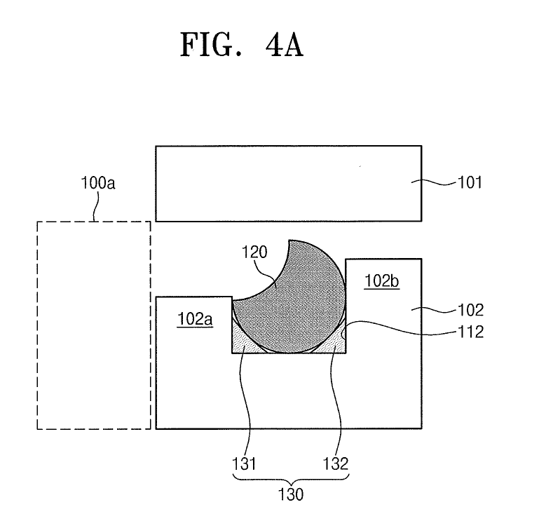

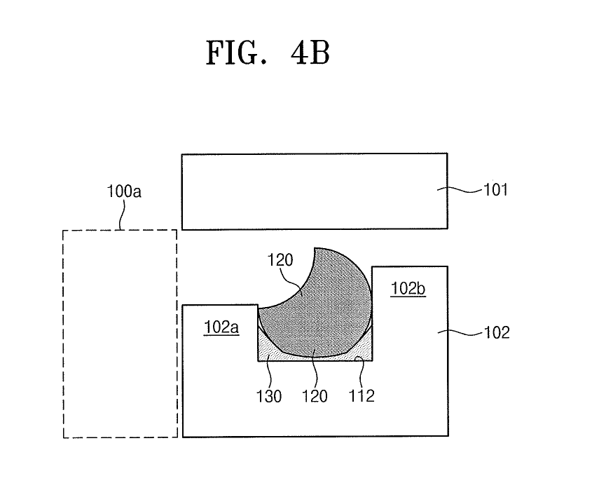

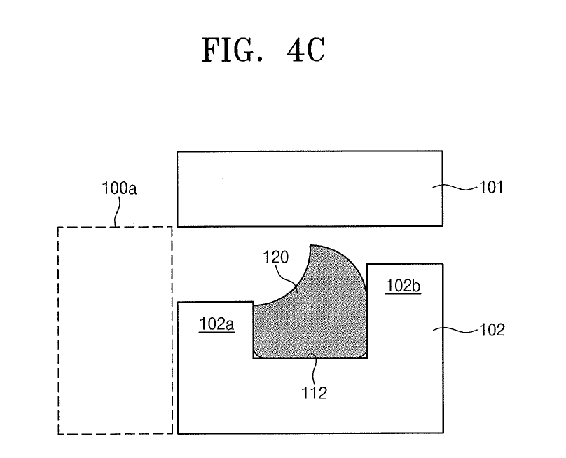

FIGS. 4A to 4C illustrate modified examples of the portion in FIG. 2A.

Referring to FIG. 4A, the groove 112 may not have a shape fitted to (e.g., a complementary shape of) an appearance of the O-ring 120. For example, the O-ring 120 may have an atypical cross-sectional shape and the groove 112 may have a rectangular cross-sectional shape. Accordingly, even if the O-ring 120 is pressured, there may be a gap between the groove 112 and the O-ring 120.

According to one embodiment, a filler 130 may be provided between the groove 112 and the O-ring 120 to fill the gap(s) therebetween. Similar to the shape of the O-ring 120 in FIG. 1D, when viewed in plan view, the filler 130 may have a ring shape extending along the groove 112. The cross-sectional shape of the filler 130 may be changed depending on that of the groove 112 and/or the O-ring 120. As an example, the filler 130 may have a triangular cross-sectional shape as shown in FIG. 4A.

The filler 130 may include a plurality of separate parts. For example, the filler 130 may include a first filler 131 at a left bottom corner of the groove 112 and a second filler 132 at a right bottom corner of the groove 112. According to another example, the filler 130 may have a unitary single body as shown in FIG. 4B.

The filler 130 may include the same polymer as the O-ring 120, or a polymer having a compressive strain property lower than the O-ring 120. For example, the filler 130 may be formed of or include at least one of polytetrafluoroethylene (PTFE), perfluoroalkoxy (PFA), polyimide, polyethylene, polychlorotrifluoroethylene (PCTFE), urethane, fluorine-based resins, polyetheretherketone (PEEK), polyvinylidenefluoride (PVDF), methycellulose (MC), nylon, polyamideiminde (PAT), polybenzimidazole (PBI), polycarbonate, or polyethyleneterephthalate (PET), or a combination thereof

Referring to FIG. 4C, the O-ring 120 may fill almost entirely or substantially all of the groove 112. For example, the O-ring 120 may be inserted into the groove 112 to prevent a gap from forming between the O-ring 120 and the groove 112. In one embodiment, the O-ring 120 may have an upper portion having a cross-sectional shape like a waxing gibbous moon, and a rectangular lower portion. In another embodiment, the O-ring 120 may have another type of atypical cross-sectional shape.

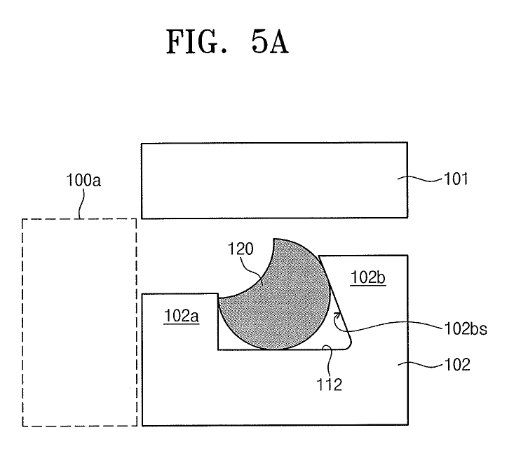

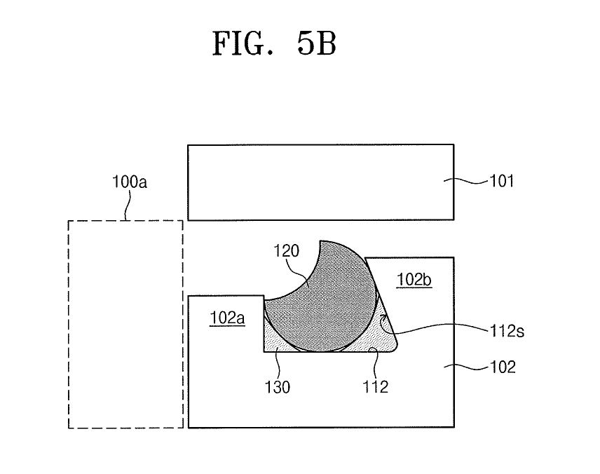

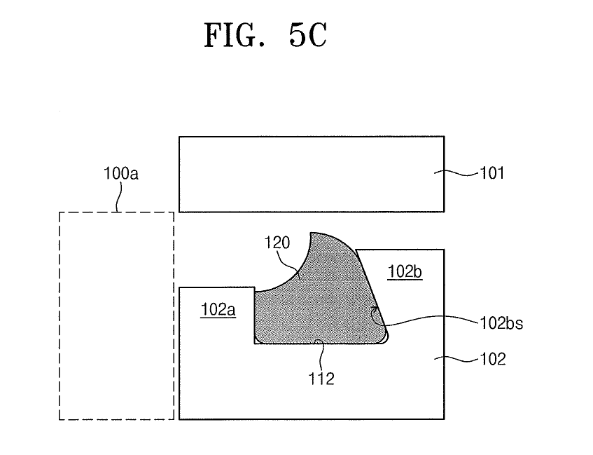

FIGS. 5A to 5C, 6A through 6C, and 7A and 7B are cross-sectional views of other examples of the portion shown in FIG. 2A. Referring to FIG. 5A, a compressed fluid (e.g., supercritical fluid) for a substrate treatment process may remain between the O-ring 120 and the groove 112. When the lower chamber 102 is separated from the upper chamber 101 to open the substrate treatment region 100a, the compressed fluid may rapidly expand. In this case, the O-ring 120 may be suddenly thrown from the groove 112.

However, according to one embodiment, to prevent such a sudden throw of the O-ring 120, the groove 112 may have a wide bottom surface and a narrow top entrance. For example, the outer wall 102b of the groove 112 may have a tapered width that increases in a direction toward the upper chamber 101. For example, the inner sidewall 102s of the outer wall 102b may be slanted toward the O-ring 120 to prevent the O-ring 120 from escaping when the lower chamber 102 is separated from the upper chamber 101 and/or in other circumstances.

Referring to FIG. 5B, the filler 130 may be provided in the groove 112 to fill a gap between the O-ring 120 and the groove 112. The filler 130 may include a plurality of separate parts as shown in FIG. 4A, or may be provided in the form of a unitary single body as shown in FIG. 4B.

Referring to FIG. 5C, the O-ring 120 may fill almost entirely or substantially all of the groove 112. For example, the O-ring 120 may have an upper portion having a cross-sectional shape like a waxing gibbous moon, a left lower portion having a cross-sectional shape like a rectangle, and a right lower portion that protrudes in a predetermined direction, e.g., rightwards. In other embodiments, the O-ring 120 may have a different type of atypical cross-sectional shape.

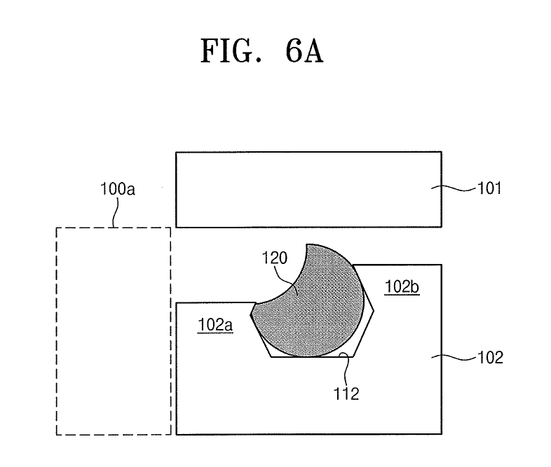

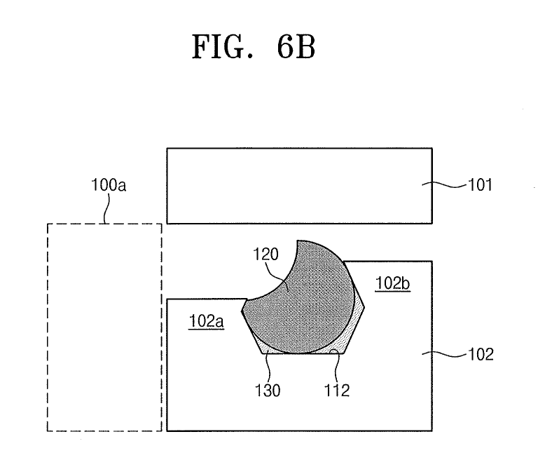

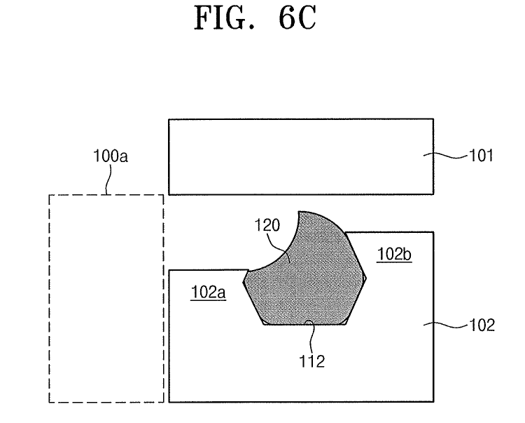

Referring to FIG. 6A, the groove 112 may have a hexagonal cross-sectional shape. Accordingly, upper portions of the inner and outer walls 102a and 102b may be slanted toward the O-ring 120 to suppress the O-ring 120 from escaping. In one embodiment, the groove 112 may have a polygonal cross-section or another cross-sectional shape different from a hexagonal shape.

Referring to FIG. 6B, the filler 130 may be provided in the groove 112 to fill a gap between the O-ring 120 and the groove 112. The filler 130 may include a plurality of filler separate parts filling the gap or may be provided in the form of a unitary single body to fill the gap.

Referring to FIG. 6C, the O-ring 120 may have a shape that fills almost entirely or substantially all of the groove 112. For example, a cross-section of the O-ring 120 may have a shape like a waxing gibbous moon with hexagonal circumference.

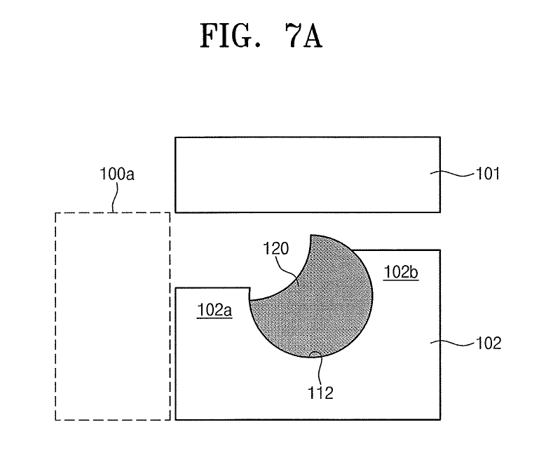

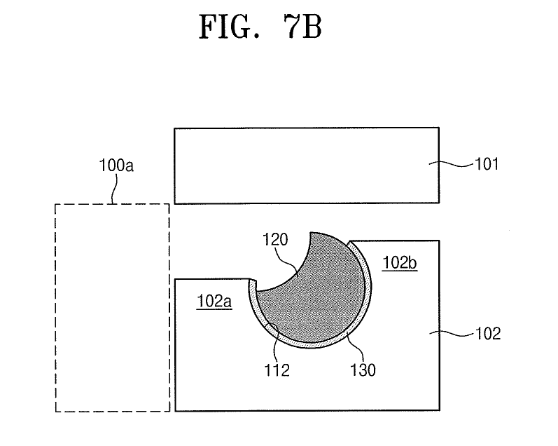

Referring to FIG. 7A, the groove 112 may have a shape or cross-section fitted to an outer circumferential shape of the O-ring 120. For example, the O-ring 120 may completely fill the groove 112.

Referring to FIG. 7B, the O-ring 120 may have a size too small to completely fill the groove 112. In this case, the filler 130 may be provided in the groove 112 to fill a gap between the O-ring 120 and the groove 112.

In accordance with one or more of the aforementioned embodiments, a substrate treatment chamber includes a sealing member (such as an O-ring) having an atypical cross-sectional shape. This shape makes it possible to prevent or suppress the O-ring from being damaged or deformed when the chamber is opened or closed. Also, the atypical cross-sectional shape allows the O-ring to have superior sealing ability, thereby reducing the likelihood of a failure during a substrate treatment process, which, in turn, may increase process yield.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. A substrate treatment apparatus, comprising:
a process chamber including a substrate treatment region between an upper chamber and a lower chamber; and
a seal on at least one of the upper or lower chambers to hermetically close the substrate treatment region, wherein the seal is at a location to prevent a gap between the upper and lower chambers, and wherein the lower chamber includes an inner wall and an outer wall defining a groove including the seal, the inner wall has a top surface lower than that of the outer wall, and the seal has an atypical cross-sectional shape with a recess facing the substrate treatment region.

2. The apparatus as claimed in claim 1, wherein:
the seal is or includes an O-ring, and
the atypical cross-sectional shape is an atypical circular shape.

3. The apparatus as claimed in claim 1, further comprising:
a filler between the seal and the groove,
wherein the filler is at a location to reduce a size of a gap between the seal and the groove.

4. The apparatus as claimed in claim 3, wherein the filler has a compressive strain property that is substantially equivalent to or lower than that of the seal.

5. The apparatus as claimed in claim 1, wherein the lower chamber is to move toward the upper chamber until the lower and upper chambers are in contact with each other, to hermetically close the substrate treatment region.

6. The apparatus as claimed in claim 1, wherein, when the lower and upper chambers are in contact with each other, the outer wall is in contact with the upper chamber and the inner wall is spaced apart from the upper chamber.

7. The apparatus as claimed in claim 1, wherein:
the outer wall has a width that increases in a direction from the lower chamber toward the upper chamber, and an inner side surface of the outer wall slants toward the seal.

8. The apparatus as claimed in claim 1, wherein:
the groove has a shape fitted to an appearance of the seal, and
the seal fills the groove.

9. A substrate treatment apparatus, comprising:
a substrate treating unit including at least one process chamber;
a fluid supply to supply a supercritical fluid to the at least one process chamber; and
a supply line valve arrangement to provide a flow path for supplying the supercritical fluid from the fluid supply to the substrate treating unit, the supply line valve arrangement including at least one supply line that includes a valve,
wherein the at least one process chamber includes:
upper and lower chambers defining a substrate treatment region and having an open/closed state that corresponds to positions of the upper and lower chambers; and a seal between the upper and lower chambers to hermetically close the substrate treatment region when the upper and lower chambers are in contact with each other,
wherein the lower chamber includes inner and outer walls defining a groove including the seal, the inner and outer walls being adjacent to the substrate treatment region and an outside of the process chamber, respectively, a top surface of the inner wall is farther from the upper chamber than a top surface of the outer wall, and the seal is or includes an O-ring having an atypical cross-section with a recess adjacent to the top surface of the inner wall.

10. The apparatus as claimed in claim 9, further comprising:
a cylinder coupled with the lower chamber to provide a driving force to move the lower chamber toward the upper chamber; and
a rod defining a path to guide the lower chamber toward the upper chamber, wherein the lower chamber is to move toward the upper chamber by the driving force from the cylinder until the lower and upper chambers are in contact with each other, to thereby hermetically close the substrate treatment region.

11. The apparatus as claimed in claim 10, wherein, when the lower and upper chambers are in contact with each other, the top surface of the outer wall is in contact with the upper chamber and the top surface of the inner wall is spaced apart from the upper chamber.

12. The apparatus as claimed in claim 9, wherein:
the outer wall has an inner side surface slanted toward the O-ring, and
the groove includes a top entrance adjacent to the upper chamber and a bottom surface having a width less than that of the top entrance.

13. The apparatus as claimed in claim 9, further comprising:
a filler between the O-ring and the groove to reduce a size of a gap between the O-ring and the groove, wherein the filler includes a polymer having a compressive strain substantially equivalent to or lower than that of the O-ring.

14. The apparatus as claimed in claim 13, wherein the O-ring and the filler include at least one of polytetrafluoroethylene, perfluoroalkoxy, polyimide, polyethylene, polychlorotrifluoroethylene, urethane, or fluorine-based resins.

15. The apparatus as claimed in claim 13, wherein:
the O-ring includes at least one of polytetrafluoroethylene, perfluoroalkoxy, polyimide, polyethylene, polychlorotrifluoroethylene, urethane, or fluorine-based resins, and
the filler includes at least one of polyetheretherketone, polyvinylidenefluoride, methycellulose, nylon, polyamideiminde, polybenzimidazole, polycarbonate, or polyethyleneterephthalate.

16. A chamber for treating a substrate, comprising:
a surface;
a groove in the surface; and
a seal in the groove, wherein the seal has a first cross-sectional shape when uncompressed and a second cross-sectional shape when compressed, and wherein the first cross-sectional shape is an atypical shape and the second cross-sectional shape does not overlap the surface at areas adjacent to the groove.

17. The chamber as claimed in claim 16, wherein the first cross-sectional shape is substantially a waxing or waning gibbous moon shape.

18. The chamber as claimed in claim 16, wherein a side wall of the groove in the surface is slanted in a direction toward the seal.

19. The chamber as claimed in claim 16, further comprising:
a filler material in the groove,
wherein the filler material is between the seal and a wall of the groove.

20. The chamber as claimed in claim 16, wherein a top surface of the seal extends above the adjacent areas of the surface when uncompressed.
